(19) United States
(12) Patent Application Publication
(10) Pub. No.: US 2023/0147283 A1
(43) Pub. Date: May 11, 2023

(54) APPARATUS FOR AND METHOD OF MANUFACTURING DISPLAY DEVICE

(71) Applicant: Samsung Display Co., Ltd., Yongin-si (KR)

(72) Inventors: Seoyeon Kim, Yongin-si (KR); Hongkyun Ahn, Yongin-si (KR); Sujung Kang, Yongin-si (KR); Jiyun Chun, Yongin-si (KR); Sangwoo Jo, Yongin-si (KR)

(21) Appl. No.: 17/982,430

(22) Filed: Nov. 7, 2022

(30) Foreign Application Priority Data
Nov. 10, 2021 (KR) 10-2021-0154287

(51) Int. Cl. H01L 51/56; H01L 51/00

(52) U.S. Cl. CPC H01L 51/56; H01L 51/0011; H01L 51/0017

(57) ABSTRACT

An apparatus for manufacturing a display device includes a mask arranged to face a substrate and a deposition source arranged to face the mask, wherein the mask includes a frame that includes a plurality of first frames that extend in a first direction and a plurality of second frames that extend in a second direction that intersects the first direction, an opening defined by the plurality of first frames and the plurality of second frames, and a plurality of laser marks located on at least one of the plurality of first frames and the plurality of second frames and generated by irradiating a laser beam.

### CROSS-REFERENCE TO RELATED APPLICATION

This application is claims priority from and the benefit of Korean Patent Application No. 10-2021-0154287, filed on Nov. 10, 2021, which is hereby incorporated by reference for all purposes as if fully set forth herein.

### BACKGROUND

### Field

Embodiments of the invention relate generally to apparatuses for and methods of manufacturing a display device and, more specifically, to apparatuses for and methods of manufacturing a display device.

### Discussion of the Background

Recently, electronic devices are widely used in various ways, such as mobile electronic devices and fixed electronic devices. These electronic devices include a display device capable of providing visual information such as images or videos to a user in order to support various functions.

A display device visually displays data and is formed by depositing various layers such as an organic layer, a metal layer, and the like. A deposition apparatus may be used to form a plurality of layers of the display device. The deposition apparatus is used so that a deposition material is ejected from a deposition source, passes through a mask, and is deposited on a substrate.

The above information disclosed in this Background section is only for understanding of the background of the inventive concepts, and, therefore, it may contain information that does not constitute prior art.

### SUMMARY

In the case of a mask of a deposition apparatus, a substrate may be damaged by contact with a substrate due to sagging, or foreign substances may be irradiated, and deposition may be poor.

To solve various issues raised above, one or more inventive concepts consistent with one or more embodiments described hereinbelow include apparatuses for and methods of manufacturing a display device including a mask for easily depositing a deposition material on a substrate.

Additional features of the inventive concepts will be set forth in the description that follows, and in part will be apparent from the description, or may be learned by practice of the inventive concepts.

According to one or more embodiments, an apparatus for manufacturing a display device includes a mask arranged to face a substrate and a deposition source arranged to face the mask, wherein the mask includes a frame that includes a plurality of first frames that extend in a first direction and a plurality of second frames that extend in a second direction that intersects the first direction, an opening defined by the plurality of first frames and the plurality of second frames, and a plurality of laser marks located on at least one of the plurality of first frames and the plurality of second frames and generated by irradiating a laser beam.

The plurality of laser marks may be arranged spaced apart in an extending direction of the frame.

The plurality of laser marks may include a first column of laser marks arranged in an extending direction of the frame and a second column of laser marks, the second column being spaced apart from the first column in a direction perpendicular to the extending direction of the frame and arranged in the extending direction of the frame.

Laser marks in the first column and laser marks in the second column may be arranged to face each other.

When viewed in the direction perpendicular to the extending direction of the frame, the laser marks in the first column may be arranged between the laser marks in the second column.

Sizes of the laser marks in the first column and the laser marks in the second column may be different from each other.

Some of distances between the plurality of laser marks may be different from each other.

The plurality of laser marks may be provided only in some of the plurality of first frames or some of the plurality of second frames.

The apparatus may further include protrusions protruding from one surface of the frame along a circumference of the opening.

The plurality of laser marks may be arranged on a surface opposite to the one surface of the frame on which the protrusions are arranged.

A thickness of the frame may be different from inner and outer thicknesses of the protrusions with respect to the protrusions.

When viewed in a direction perpendicular to the frame, the plurality of laser marks may be located between the protrusions.

The mask may be integrally provided.

According to one or more embodiments, a method of manufacturing a display device includes arranging a substrate in a chamber, arranging a mask to face the substrate, and depositing a deposition material on the substrate through the mask by using a deposition source arranged to face the mask, wherein the mask includes a frame including a plurality of first frames extending in a first direction and a plurality of second frames extending in a second direction that intersects the first direction, an opening defined by the plurality of first frames and the plurality of second frames, protrusions protruding from one surface of the frame along a circumference of the opening, and a plurality of laser marks located on at least one of the plurality of first frames and the plurality of second frames and generated by irradiating a laser beam.

The method may further include irradiating a laser beam to a plurality of points spaced apart in an extending direction of the frame.

The irradiating of the laser beam may include irradiating a laser beam to a plurality of points provided in two columns in an extending direction of the frame.

The plurality of points provided in the two columns are arranged to face each other.

The plurality of points provided in the two columns may be arranged in a zigzag manner.

The irradiating of the laser beam may further include irradiating the laser beam to melt and then solidify the frame.

The method may further include etching a remaining area except for an area in which the protrusions are arranged so that the protrusions are formed.

Other aspects, features, and advantages than those described above will become apparent from the following detailed description, claims, and drawings for implementing the disclosure.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

FIG. 1 is a schematic diagram of a display device manufactured according to an embodiment that is constructed according to principles of the invention.

FIG. 2 is a schematic cross-sectional view of a display device manufactured according to an embodiment, and may correspond to a cross-section of the display device taken along line of FIG. 1.

FIG. 3 is a cross-sectional view of an apparatus for manufacturing a display device, according to an embodiment.

FIG. 4 is a plan view of a mask according to an embodiment.

FIG. 5 is a cross-sectional view of a mask taken along line V-V′ of FIG. 4.

FIG. 6 is a diagram of a mask according to an embodiment.

FIGS. 7 to 16 are rear views of a mask according to various embodiment.

FIG. 17 is an enlarged view of a left (an -x direction) area of FIG. 5.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the x-axis, the y-axis, and the z-axis are not limited to three axes of a rectangular coordinate system. For example, the x-axis, the y-axis, and the z-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

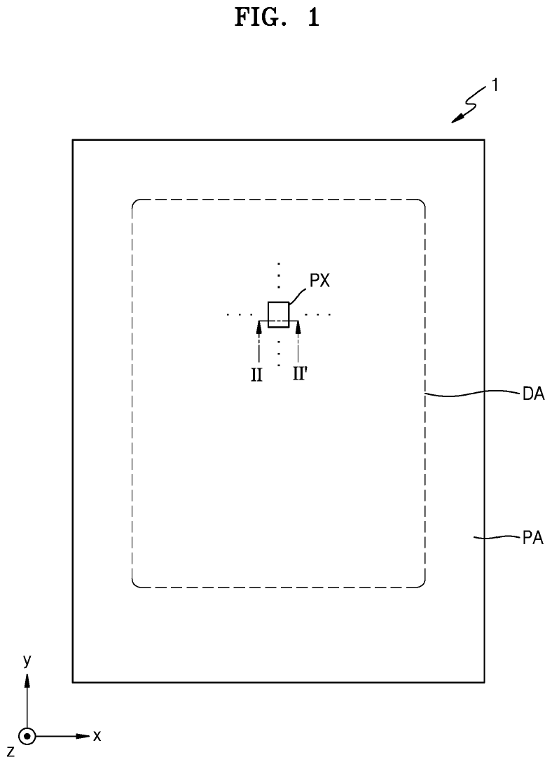

FIG. 1 is a schematic diagram of a display device 1 manufactured according to an embodiment and that is constructed according to principles of the invention.

Referring to FIG. 1, the display device 1 manufactured according to an embodiment may include a display area DA and a peripheral area PA located outside the display area DA. The display device 1 may provide an image through an array of a plurality of pixels PX that are two-dimensionally arranged in the display area DA.

The peripheral area PA, as an area that does not provide an image, may entirely or partially surround the display area DA. A driver configured to provide an electrical signal or power to a pixel circuit corresponding to each of the pixels PX may be arranged in the peripheral area PA. A pad, to which electronic devices, printed circuit boards, or the like may be electrically connected, may be arranged in the peripheral area PA.

Hereinafter, it will be described that the display device 1 includes an organic light-emitting diode (OLED) as a light-emitting element, but the display device 1 of the disclosure is not limited thereto. In another embodiment, the display device 1 may be a light-emitting display including an inorganic light-emitting diode, that is, an inorganic light-emitting display. The inorganic light-emitting diode may include a PN diode including inorganic semiconductor-based materials. When a voltage is supplied to a PN junction diode in the forward direction, holes and electrons are injected, and energy generated by recombination of the holes and the electrons is converted into light energy to emit light of a predetermined color. The inorganic light-emitting diode may have a width of a several to several hundreds of micrometers, and in some embodiments, the inorganic light-emitting diode may be referred to as a micro light-emitting diode (micro LED). In another embodiment, the display device 1 may be a quantum dot light-emitting display.

The display device 1 may be used as display screens of various products such as televisions, laptops, monitors, billboards, or Internet of Things (IOTs) as well as portable electronic devices such as mobile phones, smart phones, tablet personal computers (tablet PCs), mobile communication terminals, electronic notebooks, e-books, portable multimedia players (PMPs), navigations, or ultra-mobile PCs (UMPCs). Also, the display device 1 according to an embodiment may be used in wearable devices such as smart watches, watch phones, glass-type displays, or head mounted displays (HMDs). Also, the display device 1 according to an embodiment may be used as a vehicle's dash board, a center information display (CID) located at a vehicle's center fascia or dashboard, a room mirror display covering for a vehicle's side-view mirror, or a display screen, which is located at the back of a front seat, as entertainment for a passenger in a back seat of a vehicle.

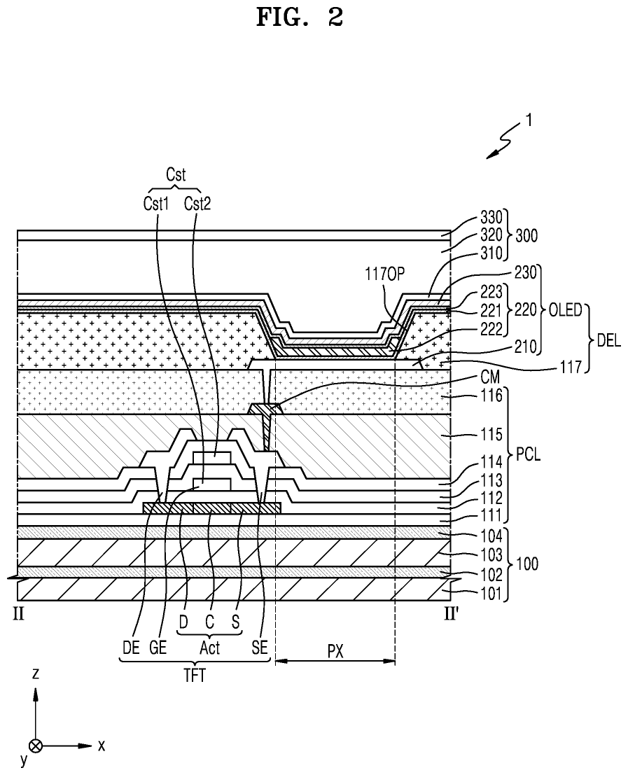

FIG. 2 is a schematic cross-sectional view of a display device manufactured using an apparatus for manufacturing a display device, according to an embodiment, and may correspond to a cross-section of a display device taken along line of FIG. 1.

Referring to FIG. 2, the display device 1 may include a stacked structure of a substrate 100, a pixel circuit layer PCL, a display element layer DEL, and an encapsulation layer 300.

The substrate 100 may be a multi-layered structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104 which are sequentially stacked in this stated order. The first base layer 101 and the second base layer 103 may include polyimide (PI), polyethersulfone (PES), polyarylate, polyetherimide (PEI), polyethyelenene napthalate (PEN), polyethyeleneterepthalate (PET), polyphenylene sulfide (PPS), polycarbonate (PC), cellulose triacetate (TAC), or/and cellulose acetate propionate (CAP). The first barrier layer 102 and the second barrier layer 104 may include an inorganic insulation material such as silicon oxide, silicon oxynitride, and/or silicon nitride. The substrate 100 may have flexible characteristics.

The pixel circuit layer PCL may be arranged on the substrate 100. FIG. 2 illustrates that the pixel circuit layer PCL includes a thin-film transistor TFT, and a buffer layer 111, a first gate insulating layer 112, a second gate insulating layer 113, an insulating interlayer 114, a first flattening insulating layer 115, and a second flattening insulating layer 116, which are located under or/and above components of the thin-film transistor TFT.

The buffer layer 111 may reduce or block foreign substances, moisture, or external air, each penetrating from a lower portion of the substrate 100, and may provide a flat surface on the substrate 100. The buffer layer 111 may include an inorganic insulation material such as silicon oxide, silicon oxynitride, or silicon nitride, and may have a single-layered structure or a multi-layered structure, each including the above-described material.

The thin-film transistor TFT on the buffer layer 111 includes a semiconductor layer Act, and the semiconductor layer Act may include polysilicon. Alternatively, the semiconductor layer Act may include amorphous silicon, an oxide semiconductor, or an organic semiconductor. The semiconductor layer Act may include a channel area C and a drain area D and a source area S respectively at both sides of the channel area C. A gate electrode GE may overlap the channel area C.

The gate electrode GE may include a low-resistance metal material. The gate electrode GE may include a conductive material including molybdenum (Mo), aluminum (Al), copper (Cu), titanium (Ti), or the like, and may be formed of a multilayer or single layer including the material.

The first gate insulating layer 112 between the semiconductor layer Act and the gate electrode GE may include an inorganic insulation material such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), zinc oxide (ZnO2), or the like.

The second gate insulating layer 113 may cover the gate electrode GE. Similar to the first gate insulating layer 112, the second gate insulating layer 113 may include an inorganic insulation material such as silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), zinc oxide (ZnO2), or the like.

An upper electrode Cst2 of a storage capacitor Cst may be arranged on the second gate insulating layer 113. The upper electrode Cst2 may overlap the gate electrode GE thereunder. In this regard, the gate electrode GE and the upper electrode Cst2, which overlap each other with the second gate insulating layer 113 therebetween, may form the storage capacitor Cst. That is, the gate electrode GE may function as a lower electrode Cst1 of the storage capacitor Cst.

As such, the storage capacitor Cst and the thin-film transistor TFT may be formed to overlap each other. In some embodiments, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multilayer of the above-described material.

The insulating interlayer 114 may cover the upper electrode Cst2. The insulating interlayer 114 may include silicon oxide (SiO2), silicon nitride (SiNX), silicon oxynitride (SiON), aluminum oxide (Al2O3), titanium oxide (TiO2), tantalum oxide (Ta2O5), hafnium oxide (HfO2), zinc oxide (ZnO2), or the like. The insulating interlayer 114 may be a single layer or multilayer including the above-described inorganic insulation material.

A drain electrode DE and a source electrode SE may each be located on the insulating interlayer 114. The drain electrode DE and the source electrode SE may respectively be connected to the drain area D and the source area S through contact holes formed in insulating layers thereunder. The drain electrode DE and the source electrode SE may include a material with excellent conductivity. The drain electrode DE and the source electrode SE may include a conductive material including molybdenum (Mo), aluminum (Al), copper (Cu), titanium (Ti), or the like, and may be formed of a multilayer or single layer including the material. In an embodiment, the drain electrode DE and the source electrode SE may have a multi-layered structure of Ti/Al/Ti.

The first flattening insulating layer 115 may cover the drain electrode DE and the source electrode SE. The first flattening insulating layer 115 may include an inorganic insulation material such as a general-purpose polymer such as polymethylmethacrylate (PMMA) or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and a blend thereof.

The second flattening insulating layer 116 may be arranged on the first flattening insulating layer 115. The second flattening insulating layer 116 may include the same material as the first flattening insulating layer 115, and may include an organic insulation material such as a general-purpose polymer such as PMMA or PS, a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be arranged on the pixel circuit layer PCL having the above-described structure. The display element layer DEL includes an organic light-emitting diode OLED as a display element (that is, a light-emitting element), and the organic light-emitting diode OLED may include a stacked structure of a pixel electrode 210, an intermediate layer 220, and a common electrode 230. The organic light-emitting diode OLED may emit, for example, red, green, or blue light, or may emit red, green, blue, or white light. The organic light-emitting diode OLED may emit light through an emission area, and the emission area may be defined as a pixel PX.

The pixel electrode 210 of the organic light-emitting diode OLED may be electrically connected to the thin-film transistor TFT through contact holes formed in the second flattening insulating layer 116 and the first flattening insulating layer 115 and a contact metal CM arranged on the first flattening insulating layer 115.

The pixel electrode 210 may include a conductive oxide material such as indium tin oxide (ITO), indium zinc oxide (IZO), zinc oxide (ZnO), indium oxide (In2O3), indium gallium oxide (IGO), or aluminum zinc oxide (AZO). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 210 may further include a film formed of ITO, IZO, ZnO, or In2O3 on/under the above-described reflective film.

A pixel-defining film 117 having an opening 117OP exposing a central portion of the pixel electrode 210 may be arranged on the pixel electrode 210. The pixel-defining film 117 may include an organic insulation material and/or an inorganic insulation material. The opening 117OP may define an emission area of light emitted from the organic light-emitting diode OLED. For example, a size/width of the opening 117OP may correspond to a size/width of the emission area. Therefore, a size and/or width of the pixel PX may depend on a size and/or width of the opening 117OP of the pixel-defining film 117.

The intermediate layer 220 may include an emission layer 222 formed corresponding to the pixel electrode 210. The emission layer 222 may include a polymer or low molecular weight organic material emitting a predetermined color of light. Alternatively, the emission layer 222 may include an inorganic light-emitting material or quantum dots.

In an embodiment, the intermediate layer 220 may include a first functional layer 221 and a second functional layer 223 respectively arranged under and on the emission layer 222. The first functional layer 221 may include, for example, a hole transport layer, or may include a hole transport layer and a hole injection layer. The second functional layer 223, as a component arranged on the emission layer 222, may include an electron transport layer and/or an electron injection layer. The first functional layer 221 and/or the second functional layer 223 may be a common layer formed to entirely cover the substrate 100 as with the common electrode 230 described later.

The common electrode 230 is arranged above the pixel electrode 210, and may overlap the pixel electrode 210. The common electrode 230 may include a conductive material with a low work function. For example, the common electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the common electrode 230 may further include a layer including materials such as ITO, IZO, ZnO, or In2O3 on the (semi)transparent layer including the above-described material. The common electrode 230 may be integrally formed to entirely cover the substrate 100.

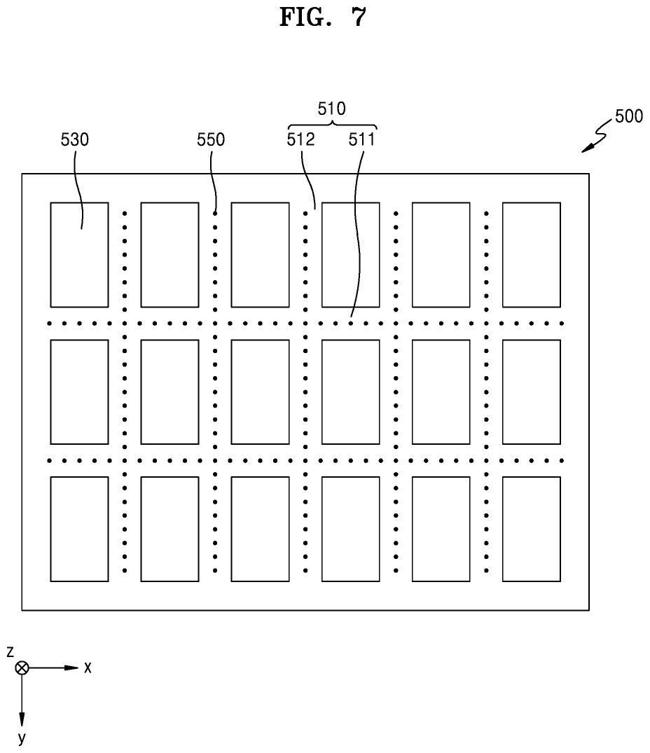

The encapsulation layer 300 is arranged on the display element layer DEL, and may cover the display element layer DEL. The encapsulation layer 300 may include at least one inorganic encapsulation layer and at least one organic encapsulation layer, and as an embodiment, FIG. 7 illustrates that the encapsulation layer 300 includes a first inorganic encapsulation layer 310, an organic encapsulation layer 320, and a second inorganic encapsulation layer 330 that are sequentially stacked in this stated order.

The first inorganic encapsulation layer 310 and the second inorganic encapsulation layer 330 may include at least one inorganic material among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acrylic resin, an epoxy-based resin, polyimide, and polyethylene. In an embodiment, the organic encapsulation layer 320 may include acrylate. The organic encapsulation layer 320 may be formed by hardening a monomer or applying a polymer. The organic encapsulation layer 320 may have transparency.

A touch sensor layer may be arranged on the encapsulation layer 300, and an optical functional layer may be arranged on the touch sensor layer. The touch sensor layer may obtain coordinate information in response to an external input, for example, a touch event. The optical functional layer may reduce the reflectance of light (external light) incident on the display device, and/or may improve the color purity of light emitted from the display device. In an embodiment, the optical functional layer may include a retarder and/or a polarizer. The retarder may be a film type or a liquid crystal coating type and may include a λ/2 retarder and/or a λ/4 retarder. The polarizer may also be a film type or a liquid crystal coating type. The film type may include a stretch-type synthetic resin film, and the liquid crystal coating type may include liquid crystals arranged in a predetermined arrangement. The retarder and the polarizer may further include a protective film.

An adhesive member may be arranged between the touch electrode layer and the optical functional layer. The adhesive member may be any adhesive member generally known in the related art. The adhesive member may be a pressure sensitive adhesive (PSA).

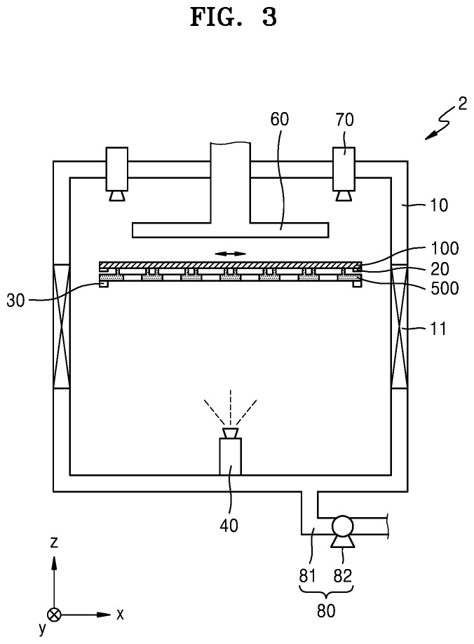

FIG. 3 is a cross-sectional view of an apparatus for manufacturing a display device, according to an embodiment.

Referring to FIG. 3, the display device 1 may be manufactured via an apparatus 2 for manufacturing a display device.

The apparatus 2 for manufacturing a display device may include a chamber 10, a first support 20, a second support 30, a mask 500, a deposition source 40, a magnetic force unit 60, a vision unit 70, and a pressure regulator 80.

The chamber 10 may have an inner space, and a portion of the chamber 10 may be opened. In this case, a gate valve 11 may be installed in the open portion of the chamber 10. In this case, the open portion of the chamber 10 may be opened or closed according to the operation of the gate valve 11.

The substrate 100 may be placed on and supported by the first support 20. In this case, the first support 20 may be in the form of a plate fixed inside the chamber 10. In another embodiment, the first support 20 may be in the form of a shuttle on which the substrate 100 is placed and that is linearly movable within the chamber 10. In another embodiment, the first support 20 may include an electrostatic chuck or an adhesive chuck, which is arranged in the chamber 10, so that the first support 20 is fixed to the chamber 10 or movable up and down inside the chamber 10. For convenience of explanation, the following will be described on the assumption that the first support 20 is in the form of a plate fixed inside the chamber 10.

The mask 500 may be seated on the second support 30. In this case, the second support 30 may be arranged inside the chamber 10. The second support 30 may precisely adjust a position of the mask 500. In this case, the second support 30 may include a separate driver or an alignment unit to move the mask 500 in different directions.

In another embodiment, the second support 30 may be in the form of a shuttle. In this case, the mask 500 is placed on the second support 30, and the mask 500 may be transportable. For example, the second support 30 may move to the outside of the chamber 10 and enter the chamber 10 from the outside of the chamber 10 after the mask 500 is placed.

In the above case, the first support 20 and the second support 30 may be integrally formed. In this case, the first support 20 and the second support 30 may include a movable shuttle. In this case, the first support 20 and the second support 30 includes a structure for fixing the mask 500 and the substrate 100 in a state in which the substrate 100 is placed on the mask 500, and may linearly move the substrate 100 and the mask 500 at the same time.

However, for convenience of explanation, the following will be described on the assumption that the first support 20 and the second support 30 are formed to be separated from each other and located at different positions, and the first support 20 and the second support 30 are arranged inside the chamber 10.

The deposition source 40 may be arranged to face the mask 500. In this case, the deposition source 40 may receive a deposition material, and vaporize or sublime the deposition material by applying heat to the deposition material. The deposition source 40 may be arranged to be fixed inside the chamber 10 or may be arranged inside the chamber 10 to be able to move linearly in one direction. However, for convenience of description, the following will be described on the assumption that the deposition source 40 is arranged to be fixed inside the chamber 10.

The mask 500 may be arranged inside the chamber 10. The mask 500 may be arranged to face the substrate 100. The mask 500 may include a plurality of openings 530. The deposition material may be deposited on the substrate 100 through the openings 530. The mask 500 is described below in detail.

The magnetic force unit 60 may be arranged inside the chamber 10 to face the substrate 100. In this case, the magnetic force unit 60 may apply force on the mask 500 toward the substrate 100 by applying magnetic force to the mask 500. In particular, the magnetic force unit 60 may prevent the mask 500 from sagging and allow the mask 500 to be adjacent to the substrate 100. Also, the magnetic force unit 60 may maintain a uniform distance between the mask 500 and the substrate 100.

The vision unit 70 is installed in the chamber 10, and may capture images of positions of the substrate 100 and the mask 500. In this case, the vision unit 70 may include a camera for capturing images of the substrate 100 and the mask 500. The positions of the substrate 100 and the mask 500 may be identified based on the images captured by the vision unit 70, and based on the images, the first support 20 may precisely adjust the position of the substrate 100 or the second support 30 may precisely adjust the position of the mask 500. However, the following will be described on the assumption that the second support 30 precisely adjusts a position of the mask 500 to arrange positions of the substrate 100 and the mask 500.

The pressure regulator 80 may be connected to the chamber 10 and may regulate a pressure inside the chamber 10. For example, the pressure regulator 80 may regulate a pressure inside the chamber 10 to be equal or similar to atmospheric pressure. Also, the pressure regulator 80 may regulate a pressure inside the chamber 10 to be equal or similar to a vacuum state.

The pressure regulator 80 may include a connection pipe 81 connected to the chamber 10 and a pump 82 installed on the connection pipe 81. In this case, according to the operation of the pump 82, external air may be introduced through the connection pipe 81, or a gas inside the chamber 10 may be guided to the outside through the connection pipe 81.

The apparatus 2 for manufacturing a display device may be used to manufacture the display device 1. Specifically, when the pressure regulator 80 makes the inside of the chamber 10 equal or similar to atmospheric pressure, the gate valve 11 may operate to open the open portion of the chamber 10.

Next, the substrate 100 may be inserted from the outside of the chamber 10 into the inside thereof. In this case, the substrate 100 may be inserted into the chamber 10 in various manners. For example, the substrate 100 may be inserted into the chamber 10 from the outside of the chamber 10 via a robot arm arranged outside the chamber 10. In another embodiment, when the first support 20 is formed in the form of a shuttle, after the first support 20 may be carried out to the outside of the chamber 10 from the inside of the chamber 10, the substrate 100 may be placed on the first support 20 via a separate robot arm arranged outside the chamber 10, and the first support 20 may be inserted into the chamber 10 from the outside of the chamber 10. For convenience of explanation, the following will be described on the assumption that the substrate 100 is inserted into the chamber 10 from the outside of the chamber 10 via a robot arm arranged outside the chamber 10.

The mask 500 may be arranged inside the chamber 10 as described above. In another embodiment, the mask 500 may be inserted into the chamber 10 from the outside of the chamber 10 in the same or similar manner as the substrate 100. However, for convenience of explanation, the following will be described on the assumption that only the substrate 100 is inserted into the chamber 10 from the outside of the chamber 10 in a state in which the mask 500 is arranged inside the chamber 10.

In the above case, in another embodiment, as described above, the first support 20 and the second support 30 may form a shuttle shape and may be inserted into the chamber 10 from the outside of the chamber 10 after fixing the substrate 100 and the mask 500.

When the substrate 100 is inserted into the chamber 10, the substrate 100 may be placed on the first support 20. In this case, the vision unit 70 may capture images of positions of the substrate 100 and the mask 500. In particular, the vision unit 70 may capture images of a first alignment mark of the substrate 100 and a second alignment mark of the mask 500.

The positions of the substrate 100 and the mask 500 may be identified based on the captured images of first alignment mark and the second alignment mark. In this case, the apparatus 2 for manufacturing a display device includes a separate controller to identify positions of the substrate 100 and the mask 500.

When the identifying of the positions of the substrate 100 and the mask 500 is completed, the second support 30 may precisely adjust the position of the mask 500.

Next, the deposition source 40 operates to supply a deposition material to the mask 500, and the deposition material that has passed through the plurality of openings 530 of the mask 500 may be deposited on the substrate 100. In this case, the pump 82 may maintain a pressure inside the chamber 10 at or similar to that of a vacuum by sucking out a gas from inside the chamber 10 and emitting it to the outside.

In the above case, the deposition material may be deposited on the substrate 100 through the openings 530 of the mask 500. In this case, the mask 500 may provide pattern holes corresponding to areas where the deposition material is deposited on the substrate 100. Accordingly, a plurality of layers stacked on the display device 1, for example, a counter electrode, may be formed.

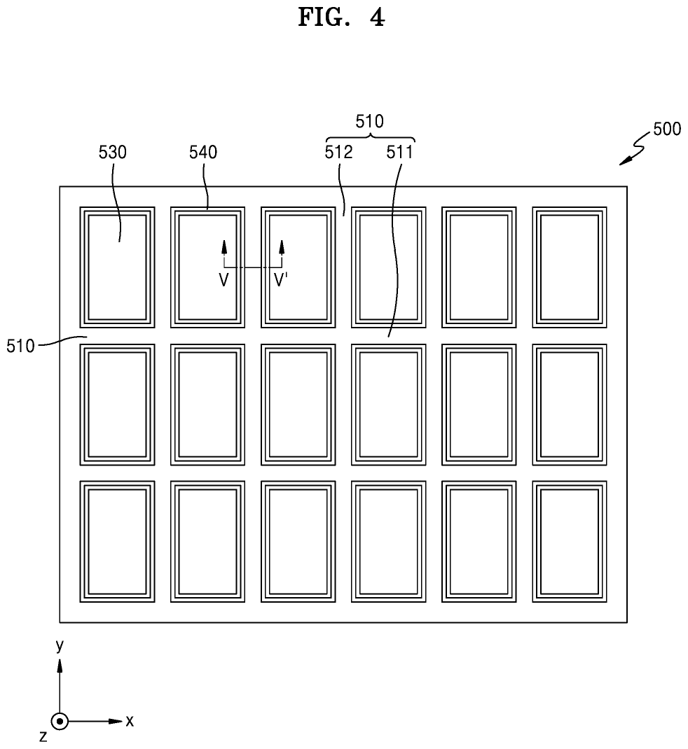

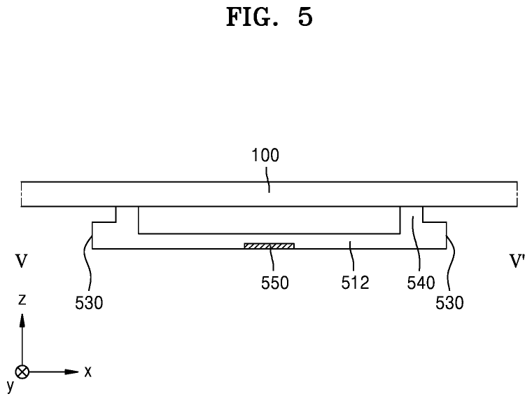

FIG. 4 is a plan view of a mask according to an embodiment. FIG. 5 is a cross-sectional view of a mask taken along line V-V of FIG. 4. A substrate is shown together in FIG. 5 for convenience of explanation.

Referring to FIGS. 4 and 5, the mask 500 may be mask included in the apparatus 2 for manufacturing a display device. In an embodiment, the mask 500 may be an open mask, that is, a mask for depositing a deposition material on an entire surface of a substrate. In other words, sizes of the openings 530 of the mask 500 may correspond to a size of the display device 1. A deposition material may pass through the openings 530 of the mask 500 to form an unpatterned layer on the substrate.

The mask 500 may include a frame 510 for forming a body of the mask 500. In an embodiment, the frame 510 may include a metal material. Specifically, the frame 510 may include a first frame 511 extending in a first direction (for example, an x direction of FIG. 4) and a second frame 512 extending in a second direction (for example, a y direction of FIG. 4) intersecting the first direction.

The first frame 511 extending in the first direction may include a plurality of first frames 511 spaced apart from each other in the second direction. Among the plurality of first frames 511 spaced apart from each other in the second direction, first frames 511 at both ends may correspond to an outer circumference of the mask 500, specifically, horizontal sides of the outer circumference.

The second frame 512 extending in the second direction may include a plurality of second frames 512 spaced apart in the first direction. Among the plurality of second frames 512 spaced apart in the first direction, second frames 512 at both ends may correspond to an outer circumference of the mask 500, specifically, vertical sides of the outer circumference.

In this case, the first frame 511 and the second frame 512 may intersect each other. In an embodiment, the first frame 511 and the second frame 512 may vertically intersect each other. In this case, the mask 500 may have a rectangular or square shape in a plan view.

In an embodiment, the first frame 511 and the second frame 512 may be integrally formed. That is, a portion where the first frame 511 and the second frame 512 intersect each other is integrally formed, and may or may not overlap each other.

The plurality of first frames 511 and the plurality of second frames 512 may define an opening 530. The first frames 511 may define horizontal sides of the opening 530, and the second frames 512 may define vertical sides of the opening 530.

The opening 530 may include a plurality of openings 530, and the plurality of openings 530 may be spaced apart from each other at regular distances. As described above, a deposition material may be deposited on the substrate 100 through the plurality of openings 530.

Also, the mask 500 may include a protrusion 540. The protrusion 540 may protrude from one surface of the frame 510, for example, an upper surface thereof. The protrusion 540 may be continuously arranged along a circumference of the opening 530 to form a closed-loop. The protrusion 540 may be in contact with the substrate 100 and may separate the opening 530 from the substrate 100.

In an embodiment, the protrusion 540 may be arranged apart from a circumference of the opening 530 to the outside. However, embodiments are not limited thereto, and in an embodiment, the protrusion 540 may not be arranged apart from the circumference of the opening 530 to the outside, and the protrusion 540 may be arranged to overlap the circumference of the opening 530. That is, the protrusion 540 may form an inner surface of the opening 530. For convenience of description, the following will be described on the assumption that the protrusion 540 is spaced apart from a circumference of the opening 530 to the outside.

In an embodiment, a thickness of the frame 510 may be different from inner and outer thicknesses of the protrusion 540, with respect to the protrusion 540. Specifically, an inner side with respect to the protrusion 540, that is, a thickness of the frame 510 forming an inner surface of the opening 530, may be greater than an outer side with respect to the protrusion 540, that is, a thickness of the frame 510 between a plurality of protrusions 540. Accordingly, a shadow (a phenomenon of not being deposited with the normal deposition thickness), especially, an outer shadow, may be improved. Here, the shadow includes an outer shadow and an inner shadow, wherein the outer shadow denotes that a deposition material is deposited on an area where deposition is unnecessary, and the inner shadow denotes that a deposition material is partially deposited on an area where deposition is necessary.

However, embodiments are not limited thereto, and for example, a thickness of the frame 510 may be equal to inner and outer thicknesses of the protrusion 540, with respect to the protrusion 540. As such, a shadow may be adjusted by adjusting a thickness of the frame 510 with respect to the protrusion 540.

In an embodiment, the protrusion 540 may be formed by etching the mask 500. Specifically, the protrusion 540 may be formed by etching remaining areas of the mask 500 except for an area where the protrusion 540 is arranged.

The mask 500 may further include a laser mark 550. The laser mark 550 may be arranged on one surface of the frame 510, for example, on a surface opposite to a surface on which the protrusion 540 is arranged. The laser mark 550 may be a mark generated when a laser beam is irradiated to a portion of the frame 510 and the frame 510 is melted and then re-s solidified.

In an embodiment, an area of the frame 510, in which the laser mark 550 is located, may have a different density from an area of the frame 510, in which the laser mark 550 is not located. For example, an area of the frame 510, in which the laser mark 550 is located, may have greater number of particles having a face-centered cubic structure (FCC), as compared to an area of the frame 510, in which the laser mark 550 is not located. Also, an area of the frame 510, in which the laser mark 550 is located, may have less number of particles having a body-centered cubic structure (BCC), as compared to an area of the frame 510, in which the laser mark 550 is not located.

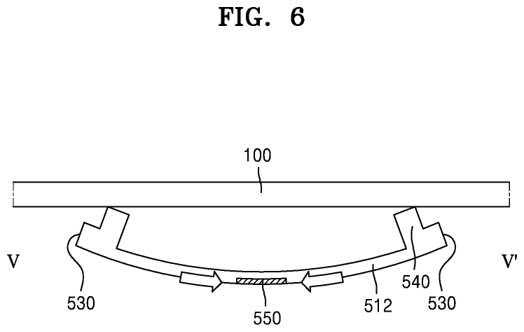

FIG. 6 is a diagram of the mask 500 according to an embodiment. FIG. 6 shows an exaggerated curvature to show a force acting on the mask 500. An arrow indicates a force acting on the mask 500, especially, the frame 510.

Referring to FIG. 6, as described above, when a laser beam is irradiated to the frame 510, the frame 510 may be melted and then re-solidified to have a different density. Specifically, as particles change from a BCC to a FCC, a contractile force may be applied toward an area of the frame 510 to which the laser beam is irradiated, in which the laser mark 550 is located. Accordingly, sagging of the frame 510 may be prevented. Specifically, as a contractile force is applied toward the laser mark 550 on the frame 510, for example, sagging of the frame 510 as shown in FIG. 6 may be prevented. Also, a defect may be prevented from occurring due to a contact of a circumference of the opening 530 with the substrate 100 by sagging of the frame 510.

The laser mark 550 may be located at the center of a width (a length in an x direction of FIG. 5) of the frame 510. Accordingly, in sagging of the width of the frame 510, a contractile force is equally applied to both sides with respect to the laser mark 550, so that the sagging may be improved.

In an embodiment, the laser mark 550 may be located between a plurality of protrusions 540. Accordingly, the frame 510 sags in a width direction as shown in FIG. 6, thereby preventing the protrusion 540 from rotating, and may be allowed to be re-unbent in an opposite direction thereof.

FIGS. 7 to 16 are rear views of a mask according to various embodiment. Specifically, a rear surface of the mask 500 shown in FIG. 4 is shown.

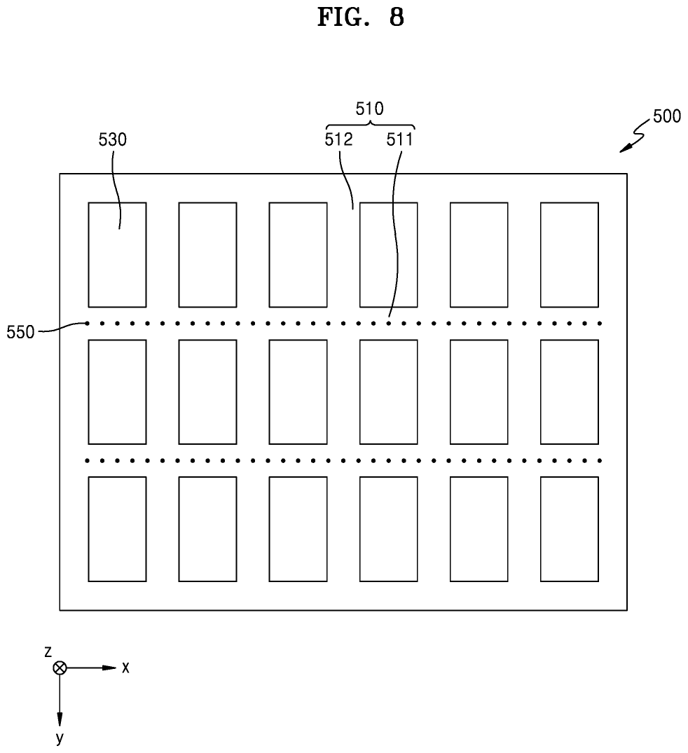

Referring to FIGS. 7 and 8, laser marks 550 may be arranged spaced apart from each other in a length direction of the frame 510, specifically, at least one of the first frame 511 and the second frame 512. That is, as shown in FIG. 7, the laser marks 550 may be arranged spaced apart from each other in a length direction (an x direction of FIG. 7) of the first frame 511 and in a length direction (a y direction of FIG. 7) of the second frame 512. Alternatively, as shown in FIG. 8, the laser marks 550 may be arranged spaced apart from each other in a length direction (an x direction of FIG. 8) of the first frame 511 and may not be arranged in the length direction of the second frame 512. Alternatively, the laser marks 550 may be arranged spaced apart from each other in a length direction (a y direction of FIG. 8) of the second frame 512 on the contrary. As such, the laser marks 550 may be arranged in consideration of an area in which sagging may occur. Hereinafter, the laser marks 550 of FIG. 7 are mainly described.

In an embodiment, a plurality of laser marks 550 may be arranged spaced apart from each other at the same distance. For example, a distance between a plurality of laser marks 550 spaced apart from each other along the first frame 511 may be equal to a distance between a plurality of laser marks 550 spaced apart from each other along the second frame 512.

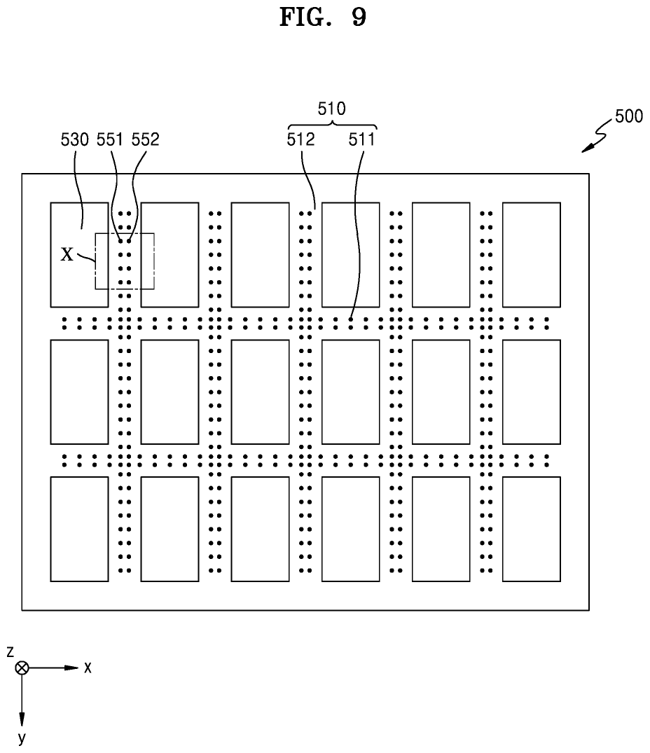

Referring to FIG. 9, a plurality of laser marks 550 may be arranged in a plurality of columns. Because laser marks 550 arranged on the first frame 511 and the second frame 512 are similar, the second frame 512 is mainly described.

In an embodiment, the plurality of laser marks 550 may include a first column 551 arranged in a length direction (a y direction of FIG. 9) of the second frame 512 and a second column 552 arranged in the length direction of the second frame 512 and spaced apart from the first column 551 in a direction (an x direction of FIG. 9) perpendicular to the length direction of the second frame 512.

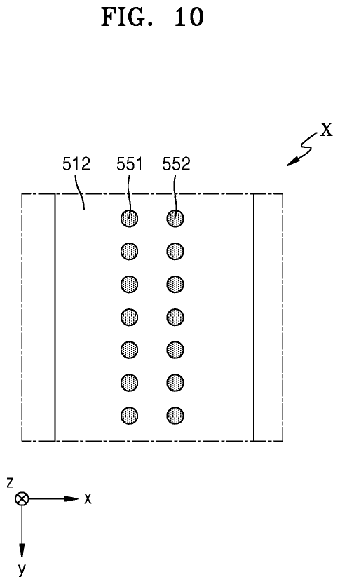

FIGS. 10 to 12 are enlarged views of an IX area of FIG. 9.

Referring to FIG. 10, a distance between laser marks 550 in the first column 551 may be equal to a distance between laser marks 550 in the second column 552.

Also, the laser marks 550 in the first column 551 and the laser marks 550 in the second column 552 may be arranged to face each other. Accordingly, the first column 551 and the second column 552 may be spaced apart from each other at the same distance with respect to the center of a width of the second frame 512. In other words, the first column 551 and the second column 552 may be symmetrical with each other with respect to the center of the width of the second frame 512.

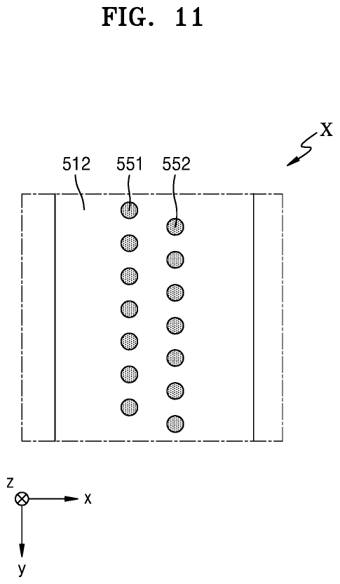

Referring to FIG. 11, in another embodiment, laser marks 550 in the first column 551 and laser marks 550 in the second column 552 may be arranged in a zigzag manner. That is, when viewed in a direction (an x direction of FIG. 11) perpendicular to a length direction (a y direction of FIG. 11) of the second frame 512, a laser mark 550 in the first column 551 may be located between two adjacent laser marks 550 in the second column 552. Accordingly, the laser marks 550 may be equally arranged in the length direction of the second frame 512, thereby preventing sagging of the frame 510.

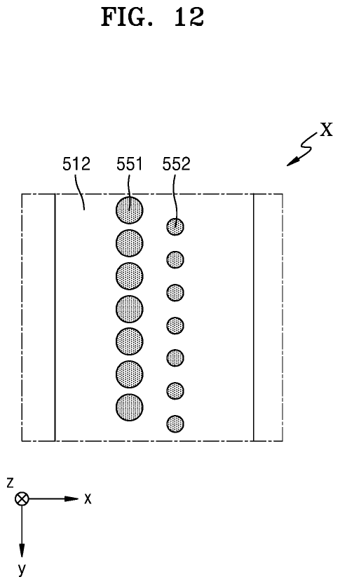

Referring to FIG. 12, in this case, a size of a laser mark 550 in the first column 551 may be different from a size of a laser mark 550 in the second column 552. For example, the laser mark 550 in the first column 551 may be greater than the laser mark 550 in the second column 552. Accordingly, in the second frame 512, laser marks 550 in the second column 552, which are smaller in size, are arranged between laser marks 550 in the first column 551, and thus, a space for arrangement of the laser marks 550 may be efficiently used. Also, the laser marks 550 in the first column 551 may have different sizes. For example, the laser marks 550 in the first column 551 may be arranged to alternately have a large size and a small size. In this case, the laser marks 550 in the second column 552 may also be arranged to alternately have a large size and a small size in the same manner as the laser marks 550 in the first column 551. In this case, a laser mark 550 in the second column 552, which faces a laser mark 550 of a large size in the first column 551, may be of a small size. Also, a laser mark 550 in the second column 552, which faces a laser mark 550 of a small size in the first column 551, may be of a large size.

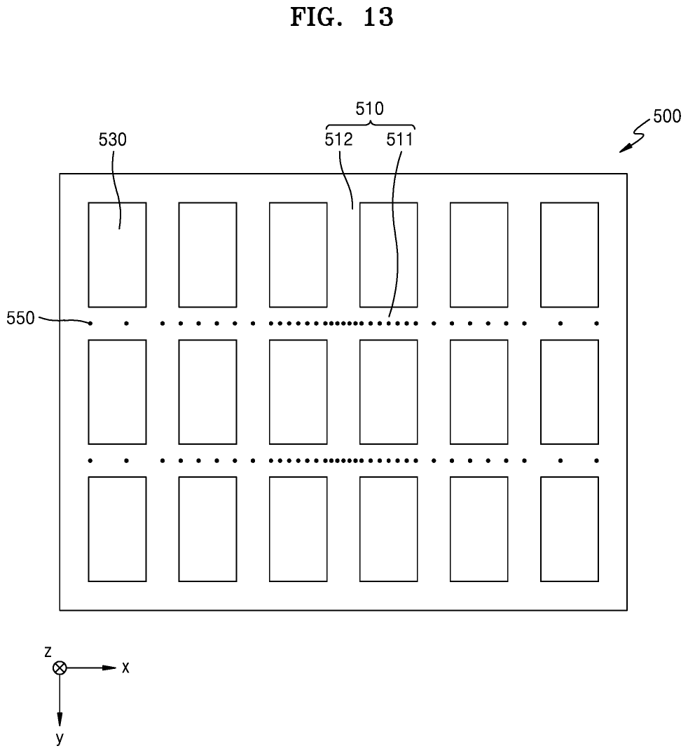

FIG. 13 is a rear view of a mask according to another embodiment. For convenience of description, FIG. 13 illustrates only laser marks 550 arranged on the first frame 511.

Referring to FIG. 13, distances between a plurality of laser marks 550 may be different from each other. In an embodiment, the distances between the plurality of laser marks 550 may decrease toward the center of the mask 500. The distances between the laser marks 550 located on the first frame 511 may decrease toward the center of the first frame 511 in a length direction (an x direction of FIG. 13). Also, distances between laser marks 550 located on the second frame 512 may decrease toward the center of the second frame 512 in a length direction (a y direction of FIG. 13).

Accordingly, sagging of a center portion of the mask 500, in which the greatest stress according to the sagging of the mask 500 may occur, may be further improved.

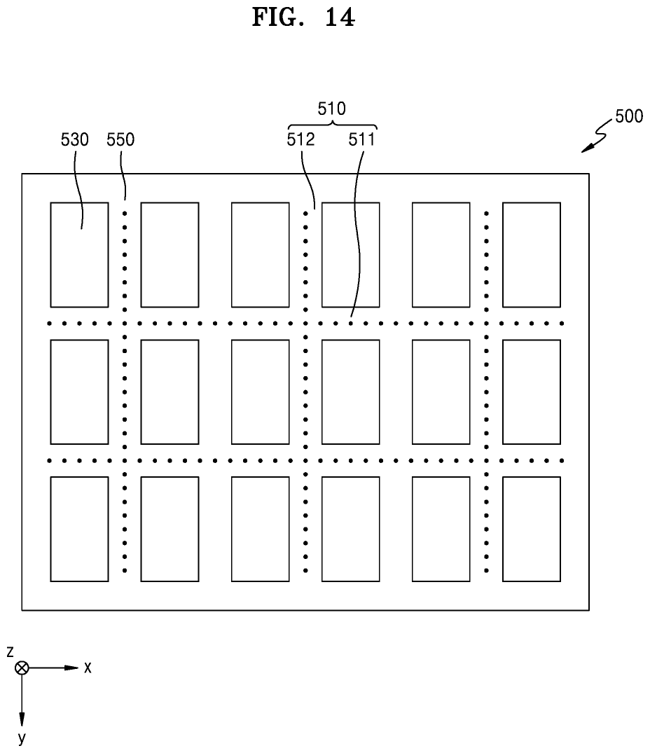

FIG. 14 is a rear view of a mask according to another embodiment.

Referring to FIG. 14, laser marks 550 may not be arranged on at least some of a plurality of first frames 511 and a plurality of second frames 512. FIG. 14 illustrates that as an example, laser marks 550 are arranged only on some of the plurality of second frames 512. However, similarly, laser marks 550 may be arranged only on some of the plurality of first frames 511. Hereinafter, the second frame 512 will be mainly described.

In an embodiment, the plurality of second frames 512 may include second frames 512 on which the laser marks 550 are arranged and second frames 512 on which the laser marks 550 are not arranged, which are alternately arranged. In this case, because a laser beam is not irradiated to an area in which sagging of the mask 500 occurs less, a laser beam may be efficiently irradiated. For example, in FIG. 14, because the second frames 512 are shorter than the first frames 511, sagging of second frames 512 in a length direction may occur less than sagging of first frames 511 in a length direction. In this case, a laser beam is not irradiated to some of the plurality of second frames 512, and thus, the laser marks 550 may be efficiently located.

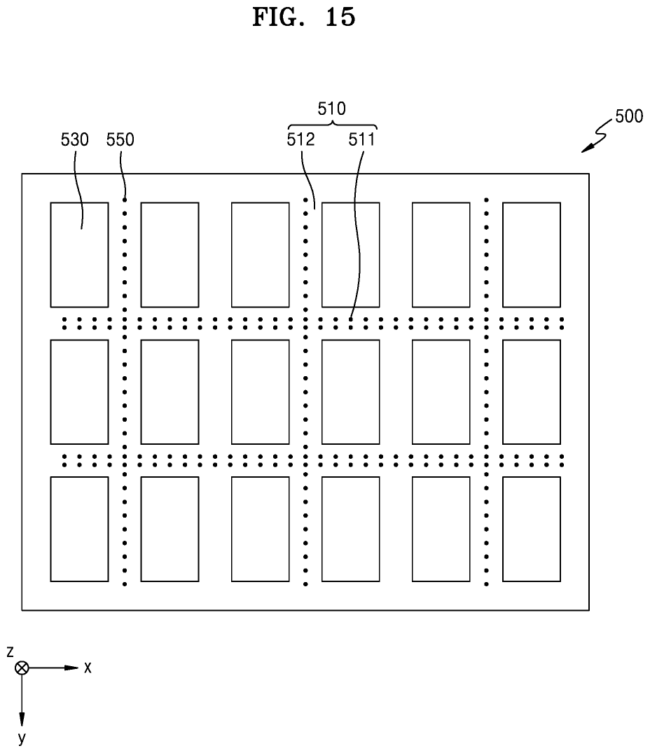

FIG. 15 is a rear view of a mask according to another embodiment. Because the present embodiment is similar to the embodiment of FIG. 14, only differences will be mainly described hereinafter.

Referring to FIG. 15, the laser marks 550 arranged in the first frames 511 in the embodiment of FIG. 14 may be provided in a plurality of columns. Accordingly, as described above, sagging of the mask 500 may be efficiently prevented by not irradiating a laser beam in a direction in which the sagging of the mask 500 occurs less and irradiating a laser beam to a plurality of columns in a direction in which the sagging of the mask 500 occurs more.

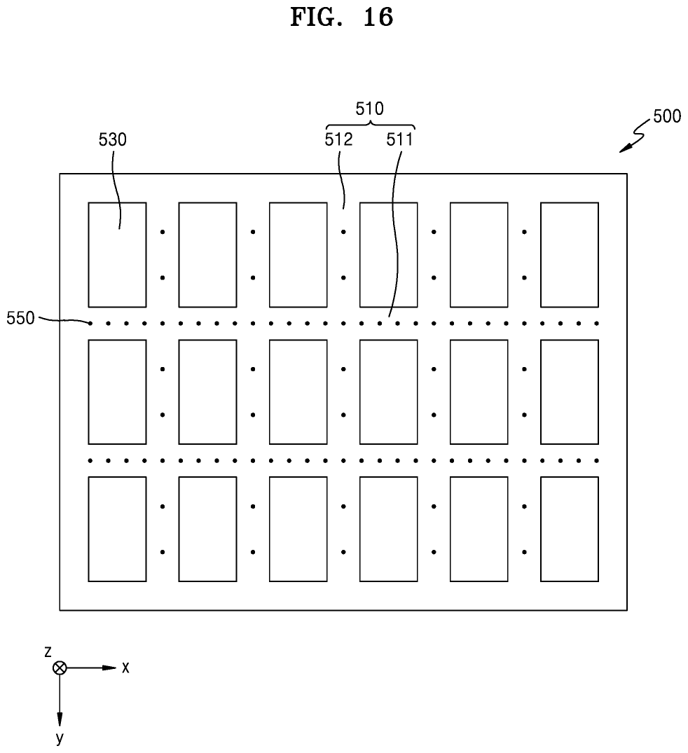

FIG. 16 is a rear view of a mask according to another embodiment. Because the present embodiment is similar to the embodiment of FIG. 14, only differences will be mainly described hereinafter.

Referring to FIG. 16, a distance between a plurality of laser marks 550 spaced apart from each other along the first frame 511 may be different from a distance between a plurality of laser marks 550 spaced apart from each other along the second frame 512. For example, a distance between a plurality of laser marks 550 spaced apart from each other along the first frame 511 may be smaller than a distance between a plurality of laser marks 550 spaced apart from each other along the second frame 512. Accordingly, as described above, sagging of the mask 500 may be efficiently prevented by sparsely irradiating a laser beam in a direction in which the sagging of the mask 500 occurs less and densely irradiating a laser beam in a direction in which the sagging of the mask 500 occurs more.

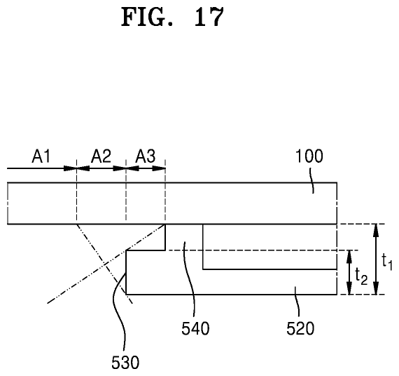

FIG. 17 is an enlarged view of a left (an -x direction) area of FIG. 5.

Referring to FIG. 17, in the mask 500 according to an embodiment, sagging or rolling of the mask 500 may be improved. Also, accordingly, a corner of the protrusion 540 or the opening 530 may be prevented from damaging the substrate 100 due to rolling of the mask

Generally, as a width of the frame 510 increases, a maximum thickness t1 of the frame 510 decreases, and a thickness t2 of the inner portion of the frame 510 with respect to the protrusion 540 increases, the risk due to sagging or rolling of the mask 500 may increase.

In the mask 500 according to an embodiment, sagging or rolling of the mask 500 may be improved by irradiating a laser beam. Accordingly, even when the frame 510 is wide, sagging or rolling of the mask 500 may be prevented, and thus, a mask 500 having a wide frame 510 may be freely used as needed.

Also, because sagging or rolling of the mask 500 is prevented by irradiating a laser beam, the maximum width t1 of the frame 510 may be reduced. Also, the thickness t2 of the inner portion of the frame 510 with respect to the protrusion 540 may be increased. This may improve a shadow when a deposition material is deposited.

Specifically, as shown in FIG. 17, a first area A1 may be an area on which a deposition material is normally deposited. A second area A2 may be an inner shadow area in which a deposition material is not formed to a certain thickness by a circumference portion of the opening 530, in relation to the maximum thickness t1 of the mask 500. A third area A3 may be an outer shadow area in which a deposition material is deposited to an area where deposition is unnecessary by a circumference portion of the opening 530, in relation to the thickness t2 of the inner portion of the frame 510 with respect to the protrusion 540.

As described above, because the maximum thickness t1 of the mask 500 may decrease, the second area A2 may be reduced. Accordingly, the first area A1, which is a normal deposition area, may be expanded. Also, because the thickness t2 of the inner portion of the frame 510 with respect to the protrusion 540 may increase, the third area A3 in which deposition is unnecessary may be reduced.

According to embodiments, apparatuses for and methods of manufacturing a display device to easily deposit a deposition material on a substrate may be provided. Accordingly, deposition defects of the display device may be prevented.

Effects of the disclosure are not limited to the effects mentioned above, and other effects not mentioned will be clearly understood by those skilled in the art from the description of the claims.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. An apparatus for manufacturing a display device, the apparatus comprising:
a mask arranged to face a substrate; and
a deposition source arranged to face the mask,
wherein the mask comprising:
a frame comprising a plurality of first frames that extend in a first direction and a plurality of second frames that extend in a second direction that intersects the first direction;
an opening defined by the plurality of first frames and the plurality of second frames;
a plurality of laser marks located on at least one of the plurality of first frames and the plurality of second frames and generated by irradiating a laser beam.

2. The apparatus of claim 1, wherein the plurality of laser marks are arranged spaced apart in an extending direction of the frame.

3. The apparatus of claim 1, wherein the plurality of laser marks comprises:
a first column of laser marks arranged in an extending direction of the frame; and
a second column of laser marks, the second column being spaced apart from the first column in a direction perpendicular to the extending direction of the frame and arranged in the extending direction of the frame.

4. The apparatus of claim 3, wherein laser marks in the first column and laser marks in the second column are arranged to face each other.

5. The apparatus of claim 3, wherein, when viewed in the direction perpendicular to the extending direction of the frame, the laser marks in the first column are arranged between the laser marks in the second column.

6. The apparatus of claim 3, wherein sizes of the laser marks in the first column and the laser marks in the second column are different from each other.

7. The apparatus of claim 1, wherein some of distances between the plurality of laser marks are different from each other.

8. The apparatus of claim 1, wherein the plurality of laser marks are provided only in some of the plurality of first frames or only in some of the plurality of second frames.

9. The apparatus of claim 1, further comprising protrusions protruding from one surface of the frame along a circumference of the opening.

10. The apparatus of claim 9, wherein the plurality of laser marks are arranged on a surface opposite to the one surface of the frame on which the protrusions are arranged.

11. The apparatus of claim 9, wherein a thickness of the frame is different from inner and outer thicknesses of the protrusions, with respect to the protrusions.

12. The apparatus of claim 9, wherein, when viewed in a direction perpendicular to the frame, the plurality of laser marks are located between the protrusions.

13. The apparatus of claim 1, wherein the mask is provided integrally.

14. A method of manufacturing a display device, the method comprising:
arranging a substrate in a chamber;
arranging a mask to face the substrate; and
depositing a deposition material on the substrate through the mask by using a deposition source arranged to face the mask,
wherein the mask comprises:
a frame comprising a plurality of first frames that extend in a first direction and a plurality of second frames that extend in a second direction that intersects the first direction;
an opening defined by the plurality of first frames and the plurality of second frames;
protrusions that protrude from one surface of the frame along a circumference of the opening; and
a plurality of laser marks located on at least one of the plurality of first frames and the plurality of second frames and generated by irradiating a laser beam.

15. The method of claim 14, further comprising irradiating a laser beam to a plurality of points spaced apart in an extending direction of the frame.

16. The method of claim 14, wherein the irradiating of the laser beam comprises irradiating a laser beam to a plurality of points provided in two columns in an extending direction of the frame.

17. The method of claim 16, wherein the plurality of points provided in the two columns are arranged to face each other.

18. The method of claim 16, wherein the plurality of points provided in the two columns are arranged in a zigzag manner.

19. The method of claim 14, wherein the irradiating of the laser beam further comprises irradiating the laser beam to melt and then solidify the frame.

20. The method of claim 14, further comprising etching a remaining area except for an area in which the protrusions are arranged so that the protrusions are formed.
